(19) United States
(12) Patent Application Publication
(10) Pub. No.: US 2019/0109199 A1
(43) Pub. Date: Apr. 11, 2019

(54) OXIDE SEMICONDUCTOR DEVICE

(71) Applicant: UNITED MICROELECTRONICS CORP., Hsin-Chu City (TW)

(72) Inventors: HAI BIAO YAO, Singapore (SG); Shao-Hui Wu, Singapore (SG); Xiang Li, Singapore (SG); HSIAO YU CHIA, Singapore (SG); Yu-Cheng Tung, Kaohsiung City (TW)

(21) Appl. No.: 15/725,288

(22) Filed: Oct. 5, 2017

(51) Int. Cl. H01L 29/49; H01L 21/225; H01L 21/02; H01L 29/786; H01L 29/04

(52) U.S. Cl. CPC H01L 29/4908; H01L 21/2251; H01L 21/02565; H01L 29/045; H01L 21/02178; H01L 29/78696; H01L 29/78693; H01L 21/02164

(57) ABSTRACT

An oxide semiconductor device includes an oxide semiconductor channel layer, a first gate dielectric layer, a first gate electrode, a source electrode, and a drain electrode. The oxide semiconductor channel layer includes a channel region. The first gate dielectric layer is disposed on the oxide semiconductor channel layer. The first gate electrode is disposed on the first gate dielectric layer. The source electrode and the drain electrode are disposed at two opposite sides of the first gate electrode in a first direction respectively. The first gate electrode includes a metal material with a work function higher than 4.7 electron volts (eV). A thickness of the oxide semiconductor channel layer is smaller than one third of a length of the channel region in the first direction.

### BACKGROUND OF THE INVENTION

### 1. Field of the Invention

The present invention relates to an oxide semiconductor device, and more particularly, to an oxide semiconductor device including an oxide semiconductor channel layer.

### 2. Description of the Prior Art

Oxide semiconductor materials, such as indium gallium zinc oxide (IGZO), have been applied in thin film transistors (TFTs) of display devices and field effect transistors (FETs) used in integrated circuits because of properties such as high mobility and relatively low leakage current. However, carriers existing in the oxide semiconductor layer at off status of the oxide semiconductor transistor will cause normally on issue for the oxide semiconductor transistor, a back side gate electrode is required to provide minus bias voltage for lowering the off current, and the power consumption will increase accordingly. In addition, the semiconductor characteristics of the oxide semiconductor materials are directly dominated by the condition of oxygen vacancies in the oxide semiconductor materials, and the material properties of the oxide semiconductor layer tend to be influenced easily by environment substances, such as moisture, oxygen, and hydrogen. Accordingly, it is important to maintain the semiconductor characteristics of the oxide semiconductor materials for improving the electrical stability and the product reliability of the oxide semiconductor device.

### SUMMARY OF THE INVENTION

It is one of the objectives of the present invention to provide an oxide semiconductor device. A gate electrode including a higher work function metal material is used to form a higher barrier height, and a thickness of an oxide semiconductor channel layer is reduced for realizing an accumulation type and fully depleted oxide semiconductor device. The structure and manufacturing process of the oxide semiconductor device may be simplified and the power consumption may be reduced accordingly.

An oxide semiconductor device is provided in an embodiment of the present invention. The oxide semiconductor device includes an oxide semiconductor channel layer, a first gate dielectric layer, a first gate electrode, a source electrode, and a drain electrode. The oxide semiconductor channel layer includes a channel region. The first gate dielectric layer is disposed on the oxide semiconductor channel layer. The first gate electrode is disposed on the first gate dielectric layer. The source electrode and the drain electrode are disposed at two opposite sides of the first gate electrode in a first direction respectively. The first gate electrode includes a metal material with a work function higher than 4.7 electron volts (eV). A thickness of the oxide semiconductor channel layer is smaller than one third of a length of the channel region in the first direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating an oxide semiconductor device according to a first embodiment of the present invention.

FIG. 2 is a schematic drawing illustrating an oxide semiconductor device according to a second embodiment of the present invention.

FIG. 3 is a schematic drawing illustrating an oxide semiconductor device according to a third embodiment of the present invention.

FIG. 4 is a schematic drawing illustrating an oxide semiconductor device according to a fourth embodiment of the present invention.

FIG. 5 is a schematic drawing illustrating an oxide semiconductor device according to a fifth embodiment of the present invention.

FIG. 6 is a schematic drawing illustrating an oxide semiconductor device according to a sixth embodiment of the present invention.

### DETAILED DESCRIPTION

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have been described in detail in order to avoid obscuring the invention.

It will be understood that when an element is referred to as being “formed” on another element, it can be directly or indirectly, formed on the given element by growth, deposition, etch, attach, connect, or couple. And it will be understood that when an elements or a layer is referred to as being “on”, “connected to”, or “coupled to” another element or layer, it can be directly on, connected or coupled to the other element or layer or intervening elements or layers may be present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer and/or section from another. Thus, a first element, component, region, layer or section discussed below could be termed a second element, component, region, layer or section without departing from the teachings of the disclosure.

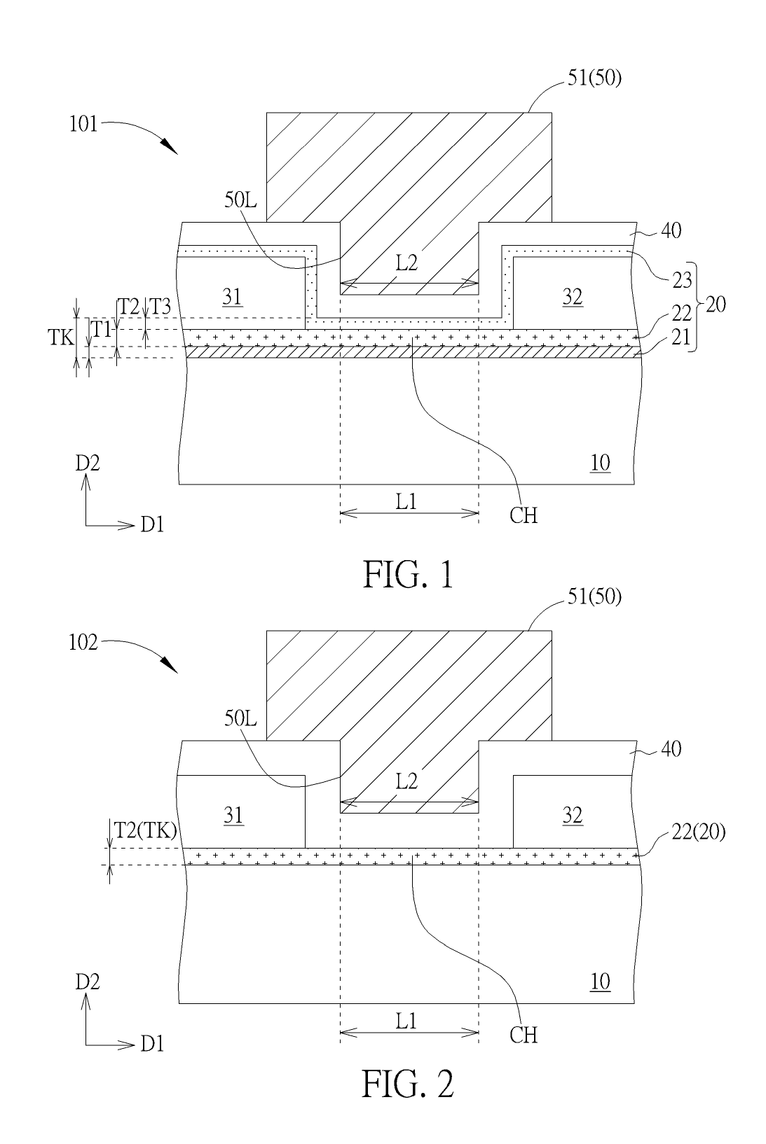

Please refer to FIG. 1. FIG. 1 is a schematic drawing illustrating an oxide semiconductor device according to a first embodiment of the present invention. As shown in FIG. 1, an oxide semiconductor device 101 is provided in this embodiment. The oxide semiconductor device 101 includes an oxide semiconductor channel layer 20, a first gate dielectric layer 40, a first gate electrode 50, a source electrode 31, and a drain electrode 32. The oxide semiconductor channel layer 20 includes a channel region CH. The first gate dielectric layer 40 is disposed on the oxide semiconductor channel layer 20. The first gate electrode 50 is disposed on the first gate dielectric layer 40. The source electrode 31 and the drain electrode 32 are disposed at two opposite sides of the first gate electrode 50 in a first direction D1 respectively. In some embodiments, the first direction D1 may be a horizontal direction orthogonal to a thick direction of the oxide semiconductor channel layer 20 (such as a second direction D2 shown in FIG. 1), but not limited thereto. The first gate electrode 50 includes a metal material 51 with a work function higher than 4.7 electron volts (eV), and a thickness TK of the oxide semiconductor channel layer 20 is smaller than one third of a length (such as a first length L1 shown in FIG. 1) of the channel region CH in the first direction D1.

In some embodiments, the oxide semiconductor channel layer 20, the first gate dielectric layer 40, the first gate electrode 50, the source electrode 31, and the drain electrode 32 may be formed on a dielectric layer 10, and the dielectric layer 10 may be formed on a substrate (not shown). The substrate may include a semiconductor substrate, a glass substrate, a plastic substrate, a ceramic substrate, or substrates made of other suitable materials. The semiconductor substrate mentioned above may include a silicon substrate, an epitaxial silicon substrate, a silicon germanium substrate, a silicon carbide substrate, or a silicon-on-insulator (SOI) substrate, but not limited thereto. For example, in some embodiments, the substrate may be a semiconductor substrate, and at least one silicon-based field effect transistor (not shown) may be formed on the substrate before the step of forming the dielectric layer 10, but not limited thereto.

The oxide semiconductor channel layer 20 may be a single layer structure or a multiple layer structure composed of a plurality of oxide semiconductor material layers stacked in the second direction D1. For example, in some embodiments, the oxide semiconductor channel layer 20 may include a first oxide semiconductor layer 21, a second oxide semiconductor layer 22, and a third oxide semiconductor layer 23 sequentially stacked in the second direction D2. The second oxide semiconductor layer 22 may be disposed on the first oxide semiconductor layer 21, and the third oxide semiconductor layer 23 may be disposed on the second oxide semiconductor layer 22. Accordingly, the thickness TK of the oxide semiconductor channel layer 20 may equal to a sum of a first thickness T1 of the first oxide semiconductor layer 21, a second thickness T2 of the second oxide semiconductor layer 22, and a third thickness T3 of the third oxide semiconductor layer 23, but not limited thereto. In some embodiments, the source electrode 31 and the drain electrode 32 may be disposed on the second oxide semiconductor layer 22, and a part of the third oxide semiconductor layer 23 may be disposed on the source electrode 31 and the drain electrode 32, but not limited thereto. In some embodiments, the material of the source electrode 31 and the drain electrode 32 may include aluminum (Al), copper (Cu), titanium aluminide (TiAl), titanium (Ti), titanium nitride (TiN), tantalum (Ta), tantalum nitride (TaN), titanium aluminum oxide (TiAlO), or other appropriate conductive materials. The first gate insulation layer 40 may include silicon oxide, silicon oxynitride, a high dielectric constant (high-k) material, or other appropriate dielectric materials. The high-k material mentioned above may include hafnium oxide (HfO₂), hafnium silicon oxide (HfSiO₄), hafnium silicon oxynitride (HfSiON), aluminum oxide (such as Al₂O₃), tantalum oxide (Ta₂O₅), zirconium oxide (ZrO₂), or other appropriate high-k materials. The work function of the metal material 51 has to be higher than 4.7 eV for forming a higher barrier height, and the metal material 51 may include nickel (Ni), cobalt (Co), gold (Au), or other suitable metal conductive materials having a work function higher than 4.7 eV. In some embodiments, the work function of the metal material 51 has to be higher than the band gap of the oxide semiconductor channel layer 20, but not limited thereto.

The material of the first oxide semiconductor layer 21, the material of the second oxide semiconductor layer 22, and the material of the third oxide semiconductor layer 23 may respectively include II-VI compounds (such as zinc oxide, ZnO), II-VI compounds doped with alkaline-earth metals (such as zinc magnesium oxide, ZnMgO), II-VI compounds doped with IIIA compounds (such as indium gallium zinc oxide, IGZO), II-VI compounds doped with VA compounds (such as stannum stibium oxide, SnSbO₂), II-VI compounds doped with VIA compounds (such as zinc selenium oxide, ZnSeO), II-VI compounds doped with transition metals (such as zinc zirconium oxide, ZnZrO), or other oxide semiconductor materials composed of mixtures of the above-mentioned materials, but not limited thereto. Additionally, the crystalline conditions of the first oxide semiconductor layer 21, the second oxide semiconductor layer 22, and the third oxide semiconductor layer 23 are also not limited. For example, the first oxide semiconductor layer 21, the second oxide semiconductor layer 22, and the third oxide semiconductor layer 23 may be amorphous IGZO (a-IGZO), crystal IGZO (c-IGZO), or C-axis aligned crystal IGZO (CAAC-IGZO). In some embodiments, the second oxide semiconductor layer 22 may be an oxide semiconductor layer having relatively lower contact resistance between the source electrode 31 and the second oxide semiconductor layer 22 and/or between the drain electrode 32 and the second oxide semiconductor layer 22 in comparison with the first oxide semiconductor layer 21, but not limited thereto. In other words, components of first oxide semiconductor layer 21, the second oxide semiconductor layer 22, and the third oxide semiconductor layer 23 may be different from one another for some design considerations. For example, an electron mobility of the first oxide semiconductor layer 21 and an electron mobility of the third oxide semiconductor layer 23 may be higher than an electron mobility of the second oxide semiconductor layer 22 for enhancing the on-current of the oxide semiconductor device 101, but not limited thereto. In some embodiments, the third oxide semiconductor layer 23 and the first oxide semiconductor layer 21 may also be used as a barrier layer for blocking substance such as silicon from entering the second oxide semiconductor layer 22. Therefore, the concentration of impurities in the second oxide semiconductor layer 22 or in the vicinity of the interface between the first oxide semiconductor layer 21 and the second oxide semiconductor layer 22 and/or between the second oxide semiconductor layer 22 and the third oxide semiconductor layer 23 may be reduced. In some embodiments, the material of the dielectric layer 10 may include silicon oxynitride, silicon oxide, or other appropriate dielectric materials. In some embodiments, a concentration of oxygen in the first gate dielectric layer 40 and a concentration of oxygen in the dielectric layer 10 may be higher than a concentration of oxygen in the oxide semiconductor channel layer 20. In other words, the first gate dielectric layer 40 and/or the dielectric layer 10 may be an oxygen provider for reducing hydrogenated oxygen vacancies (VoH) in the oxide semiconductor channel layer 20 and maintaining the semiconductor characteristics of the oxide semiconductor channel layer 20.

As shown in FIG. 1, the channel region CH of the oxide semiconductor channel layer 20 may be disposed between the source electrode 31 and the drain electrode 32 in the first direction D1. Additionally, a lower portion 50L of the first gate electrode 50 may be disposed between the source electrode 31 and the drain electrode 32 in the first direction D1, and a length (such as a second length L2 shown in FIG. 1) of the lower portion 50L of the first gate electrode 50 in the first direction D1 may be substantially equal to the first length L1 of the channel region CH in the first direction D1. In other words, the length of the channel region CH in the oxide semiconductor channel layer 20 may be defined by the lower portion 50L of the first gate electrode 50 disposed between the source electrode 31 and the drain electrode 32, but not limited thereto. The thickness TK of the oxide semiconductor channel layer 20 has to be smaller than one third of the first length of the channel region CH in the first direction D1 for realizing an accumulation type and fully depleted oxide semiconductor device. In other words, the oxide semiconductor channel layer 20 has to be thin enough and the work function of the first gate electrode 50 has to be higher than 4.7 eV, and the oxide semiconductor device 101 may then work as an accumulation type and fully depleted transistor. The fully depleted oxide semiconductor device may eliminate carriers in the oxide semiconductor channel layer 20 at off status, and there is no need to forma bottom gate electrode under the oxide semiconductor channel layer 20 for providing minus bias voltage at the off status and lowering off current (T_{off}) of the oxide semiconductor device 101. Therefore, the structure and manufacturing process of the oxide semiconductor device 101 may be simplified and the power consumption of the oxide semiconductor device 101 may be reduced because it is not necessary to form the bottom gate in the oxide semiconductor device 101. Additionally, the oxide semiconductor device 101 may be regarded as a top gate transistor, but not limited thereto. It is worth noting that, according to the experiment results, the oxide semiconductor device will not be a fully depleted transistor and a bottom gate electrode is still required when the thickness TK of the oxide semiconductor channel layer 20 is larger than or equal to one third of the first length L1 of the channel region CH or the work function of the first gate electrode 50 is lower than or equal to 4.7 eV.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

Please refer to FIG. 2. FIG. 2 is a schematic drawing illustrating an oxide semiconductor device 102 according to a second embodiment of the present invention. As shown in FIG. 2, the difference between the oxide semiconductor device 102 in this embodiment and the oxide semiconductor device in the first embodiment mentioned above is that the source electrode 31 and the drain electrode 32 in the oxide semiconductor device 102 may be disposed on the oxide semiconductor channel layer 20, and the first gate dielectric layer 40 may directly cover the source electrode 31 and the drain electrode 32, but not limited thereto.

Please refer to FIG. 3. FIG. 3 is a schematic drawing illustrating an oxide semiconductor device 103 according to a third embodiment of the present invention. As shown in FIG. 3, the difference between the oxide semiconductor device 103 in this embodiment and the oxide semiconductor device in the first embodiment mentioned above is that the first gate electrode 50 in the oxide semiconductor device 103 may further include a titanium nitride barrier layer 52 disposed between the metal material 51 and the first gate dielectric layer 40. The titanium nitride barrier layer 52 and the metal material 51 may be patterned by the same process for forming the first gate electrode 50, but not limited thereto. A concentration of titanium in the titanium nitride barrier layer 52 may be higher than a concentration of nitrogen in the titanium nitride barrier layer 52. In other words, the titanium nitride barrier layer 52 may be a titanium-rich barrier layer for reducing nitrogen diffusing to the first gate dielectric layer 40 and the oxide semiconductor channel layer 20. The interfacial properties between the first gate dielectric layer 40 and the oxide semiconductor channel layer 20 and/or between the third oxide semiconductor layer 23 and the second oxide semiconductor layer 22 may be improved, the interface state density between the first gate dielectric layer 40 and the oxide semiconductor channel layer 20 and/or between the third oxide semiconductor layer 23 and the second oxide semiconductor layer 22 may be reduced, and the reliability of the oxide semiconductor device 103 may be enhanced accordingly.

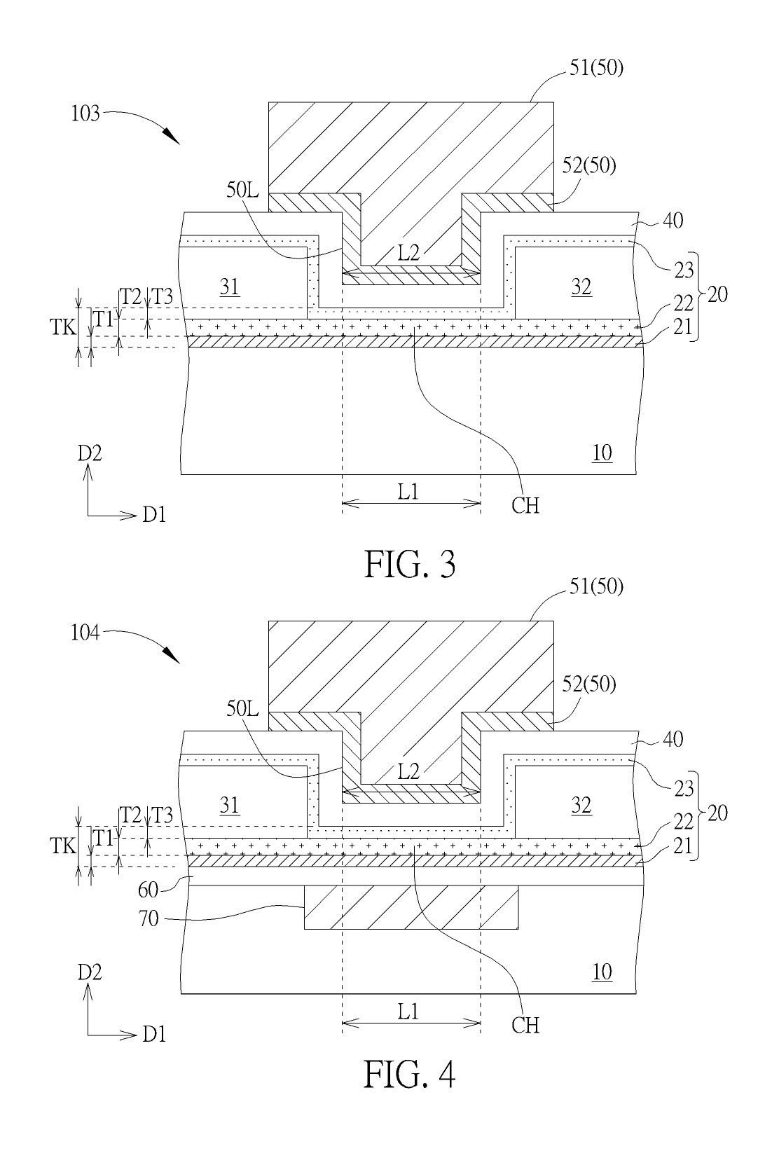

Please refer to FIG. 4. FIG. 4 is a schematic drawing illustrating an oxide semiconductor device 104 according to a fourth embodiment of the present invention. As shown in FIG. 4, the difference between the oxide semiconductor device 104 in this embodiment and the oxide semiconductor device in the third embodiment mentioned above is that the oxide semiconductor device 104 may further include a second gate dielectric layer 60 and a second gate electrode 70. The second gate dielectric layer 60 may be disposed under the oxide semiconductor channel layer 20 in the second direction D2, and the second gate electrode 70 may be disposed under the second gate dielectric layer 60. In other words, the oxide semiconductor device 104 may be regarded as a dual gate transistor, but not limited thereto. In some embodiments, a concentration of oxygen in the second gate dielectric layer 60 may be higher than the concentration of the oxygen in the oxide semiconductor channel layer 20, and the second gate dielectric layer 60 may be an oxygen provider for reducing hydrogenated oxygen vacancies (VoH) in the oxide semiconductor channel layer 20 and maintaining the semiconductor characteristics of the oxide semiconductor channel layer 20. The material of the second gate dielectric layer 60 may be similar to that of the first gate dielectric layer 40, but not limited thereto. Additionally, the second gate dielectric layer 60 may be formed on the dielectric layer 10, and the second gate electrode 70 may be formed in the dielectric layer 10. In some embodiments, the second gate electrode 70 may be formed by a process of forming at least a part of an interconnection structure (not shown) in the dielectric layer, but not limited thereto. The second gate electrode 70 may be used to enhance the on-current (Iₒₙ) of the oxide semiconductor device 104, but not limited thereto.

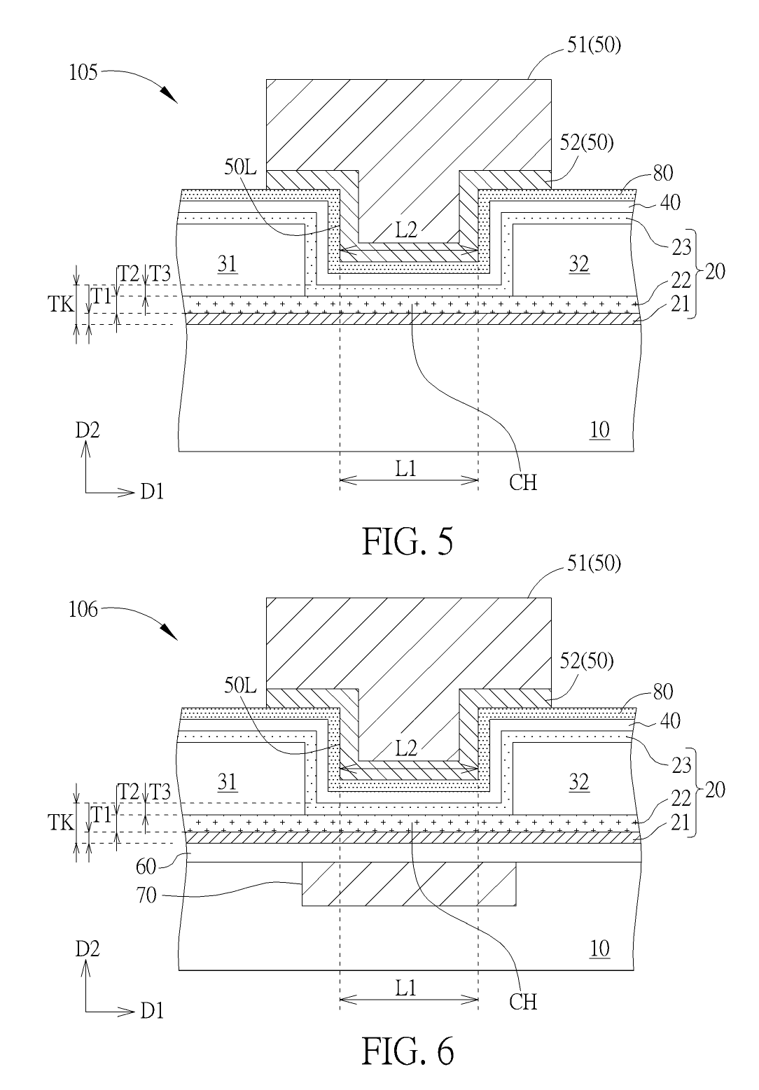

Please refer to FIG. 5. FIG. 5 is a schematic drawing illustrating an oxide semiconductor device 105 according to a fifth embodiment of the present invention. As shown in FIG. 5, the difference between the oxide semiconductor device 105 in this embodiment and the oxide semiconductor device in the third embodiment mentioned above is that the oxide semiconductor device 105 may further include a capping layer 80 disposed between the first gate electrode 50 and the first gate dielectric layer 40. A concentration of oxygen in the capping layer 80 may be higher than the concentration of the oxygen in the oxide semiconductor channel layer 20, and the capping layer 80 may be used as an oxygen provider for reducing hydrogenated oxygen vacancies in the oxide semiconductor channel layer 20 and maintaining the semiconductor characteristics of the oxide semiconductor channel layer 20. The capping layer 80 may include aluminum oxide, hafnium oxide, or other materials having relatively higher oxygen density. In some embodiments, the concentration of the oxygen in the capping layer 80 may be higher than the concentration of the oxygen in the first gate dielectric layer 40, but not limited thereto.

Please refer to FIG. 6. FIG. 6 is a schematic drawing illustrating an oxide semiconductor device 106 according to a sixth embodiment of the present invention. As shown in FIG. 6, the difference between the oxide semiconductor device 106 in this embodiment and the oxide semiconductor device in the fifth embodiment mentioned above is that the oxide semiconductor device 106 may further include the second gate dielectric layer 60 and the second gate electrode 70. The second gate dielectric layer 60 may be disposed under the oxide semiconductor channel layer 20 in the second direction D2, and the second gate electrode 70 may be disposed under the second gate dielectric layer 60. In some embodiments, the concentration of oxygen in the second gate dielectric layer 60 may be higher than the concentration of the oxygen in the oxide semiconductor channel layer 20, and the second gate electrode 70 may be used to enhance the on-current of the oxide semiconductor device 106, but not limited thereto.

To summarize the above descriptions, in the oxide semiconductor device of the present invention, the work function of the metal material of the first gate electrode is higher than 4.7 eV and the thickness of the oxide semiconductor channel layer is smaller than one third of the first length of the channel region for realizing the accumulation type and fully depleted oxide semiconductor device. Additionally, the fully depleted oxide semiconductor device may eliminate carriers in the oxide semiconductor channel layer at off status, and there is no need to form a bottom gate electrode under the oxide semiconductor channel layer for providing minus bias voltage at the off status and lowering the off current of the oxide semiconductor device. Therefore, the structure and manufacturing process of the oxide semiconductor device may be simplified and the power consumption of the oxide semiconductor device may be reduced accordingly.

Those skilled in the art will readily observe that numerous modifications and alterations of the device and method may be made while retaining the teachings of the invention. Accordingly, the above disclosure should be construed as limited only by the metes and bounds of the appended claims.

1: An oxide semiconductor device, comprising:
an oxide semiconductor channel layer comprising a channel region;
a first gate dielectric layer disposed on the oxide semiconductor channel layer;
a first gate electrode disposed on the first gate dielectric layer, wherein the first gate electrode comprises a metal material with a work function higher than 4.7 electron volts (eV), and the work function of the metal material is higher than a band gap of the oxide semiconductor channel layer; and
a source electrode and a drain electrode disposed at two opposite sides of the first gate electrode in a first direction respectively, wherein a thickness of the oxide semiconductor channel layer is smaller than one third of a length of the channel region in the first direction, wherein a lower portion of the first gate electrode is disposed between the source electrode and the drain electrode in the first direction, and a thickness of the oxide semiconductor channel layer is smaller than one third of a length of the lower portion of the first gate electrode in the first direction.

2: The oxide semiconductor device according to claim 1, wherein the channel region is disposed between the source electrode and the drain electrode in the first direction.

3. (canceled)

4: The oxide semiconductor device according to claim 1, wherein the oxide semiconductor channel layer comprises:
a first oxide semiconductor layer;
a second oxide semiconductor layer disposed on the first oxide semiconductor layer; and
a third oxide semiconductor layer disposed on the second oxide semiconductor layer, wherein the source electrode and the drain electrode are disposed on the second oxide semiconductor layer, and a part of the third oxide semiconductor layer is disposed on the source electrode and the drain electrode.

5: The oxide semiconductor device according to claim 1, wherein the source electrode and the drain electrode are disposed on the oxide semiconductor channel layer.

6: The oxide semiconductor device according to claim 1, wherein the first gate electrode further comprises a titanium nitride barrier layer disposed between the metal material and the first gate dielectric layer, and a concentration of titanium in the titanium nitride barrier layer is higher than a concentration of nitrogen in the titanium nitride barrier layer.

7: The oxide semiconductor device according to claim 1, wherein a concentration of oxygen in the first gate dielectric layer is higher than a concentration of oxygen in the oxide semiconductor channel layer.

8: The oxide semiconductor device according to claim 1,
further comprising:
a second gate dielectric layer disposed under the oxide semiconductor channel layer in a second direction orthogonal to the first direction, wherein a concentration of oxygen in the second gate dielectric layer is higher than a concentration of oxygen in the oxide semiconductor channel layer; and
a second gate electrode disposed under the second gate dielectric layer.

9. (canceled)

10: The oxide semiconductor device according to claim 1,
further comprising:
a capping layer disposed between the first gate electrode and the first gate dielectric layer, wherein a concentration of oxygen in the capping layer is higher than a concentration of oxygen in the oxide semiconductor channel layer, and the concentration of the oxygen in the capping layer is higher than a concentration of oxygen in the first gate dielectric layer.

11: The oxide semiconductor device according to claim 1, wherein the oxide semiconductor channel layer comprises indium gallium zinc oxide (IGZO).

12: The oxide semiconductor device according to claim 1, wherein the metal material of the first gate electrode comprises nickel (Ni), cobalt (Co), or gold (Au).

13-21. (canceled)
